(19) United States
(12) Patent Application Publication
(10) Pub. No.: US 2007/0170935 A1
(43) Pub. Date: Jul. 26, 2007

(54) TEST MODULE FOR WAFER

(76) Inventors: Kuei-Lin Huang, Kaohsiung City (TW); Chih-Hung Lu, Kaohsiung City (TW); Chin-Chen Chuan, Kaohsiung City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(21) Appl. No.: 11/309,678

(22) Filed: Sep. 11, 2006

(30) Foreign Application Priority Data
Jan. 20, 2006 (TW) 95102239

(51) Int. Cl. G01R 31/02

(52) U.S. Cl. 324/754

(57) ABSTRACT

A test module for wafer including a test load board, a spring pin socket, a substrate, and a plurality of probes is provided. The test load board has a plurality of first contacts. The spring pin socket in which a plurality of pogo pins is arranged is disposed on the test load board. The substrate is fixed on the spring pin socket. The substrate has a plurality of second contacts, and the pogo pins are electrically connected between the first contacts and the second contacts respectively. The plurality of probes is disposed on the substrate to electrically contact a wafer.

### CROSS-REFERENCE TO RELATED APPLICATION

This application claims the priority benefit of Taiwan application serial no. 95102239, filed on Jan. 20, 2006. All disclosure of the Taiwan application is incorporated herein by reference.

### BACKGROUND OF THE INVENTION

1. Field of the Invention

The present invention generally relates to a semiconductor inspection equipment. More particularly, the present invention relates to a wafer inspection equipment.

2. Description of Related Art

During the fabrication of integrated circuits or chips, electrical tests for the integrated circuits or chips are necessary in each step of process. Each of the integrated circuit, in the form of wafer or package, must be tested to ensure its quality and electrical properties. Due to rapid advancement of the technology, the integrated circuits with more powerful functions have been developed and the structure thereof is more complicated. Therefore, it would be highly advantageous to more rapidly and precisely test the quality of the integrated circuits.

Before the integrated circuits on a wafer are diced into individual dies, a test called wafer probing is performed on individual integrated circuits. In the wafer probing, an automatic test equipment (ATE) establishes temporary electrical contact with the integrated circuits, so as to select the qualified integrated circuits before dicing the wafer and packaging each of the integrated circuits.

FIG. 1 is a schematic view of an automatic test equipment (ATE). Referring to FIG. 1, an ATE 1000 mainly comprises a wafer test system 1100 and a test module for wafer 1200. The test module for wafer 1200 is electrically connected to the wafer test system 1100 through a cable 1300. The test module for wafer 1200 comprises a load board 1210, an ATE interface assembly 1220, and a probe card 1230. The load board 1210 is electrically connected to the wafer test system 1100. The ATE interface assembly 1220 comprises a probe contact tower, a complicated docking machine, and a lock mechanism, and so on. The detailed operating principle of the assembly 1220 is not illustrated herein, and only the usage of the probe contact tower will be generally illustrated hereinafter. The probe contact tower is adapted to electrically connect the probe card 1230 to the load board 1210 via a communicated connection terminal 1222. As such, the wafer test system 1100 transmits various test signals to an integrated circuit on the wafer via the cable 1300, circuit board 1210, ATE interface assembly 1220, and probe unit 1230, and analyzes the signal fed back by the integrated circuit to determine whether the circuit is qualified and to determine the electrical properties thereof.

However, as the ATE interface assembly has a large volume and a high price, the conventional test module for wafer has limited space utilization and is expensive. Especially in the equipment maintenance, as the assembly of each mechanical component is very complicated, the malfunction rate increases. Once malfunction occurs or the electrical test is invalid, the whole test system stops or restarts, which increases the burden of the on-line testers.

### SUMMARY OF THE INVENTION

An objective of the present invention is to provide a test module for wafer.

The present invention provides a test module for wafer, which comprises a test load board, a spring pin socket, a substrate, and a plurality of probes. The test load board has a plurality of first contacts. The spring pin socket in which a plurality of pogo pins is arranged is disposed on the test load board. The substrate is fixed on the spring pin socket. The substrate has a plurality of second contacts, and the pogo pins are electrically connected between the first contacts and the second contacts respectively. The plurality of probes is disposed on the substrate to electrically contact a wafer.

According to an embodiment of the present invention, the test module for wafer further comprises a plurality of solder balls respectively disposed on the second contacts for electrically contacting the pogo pins.

According to the test module for wafer in an embodiment of the present invention, the aforementioned substrate comprises a build-up circuit board or a laminated circuit board.

According to an embodiment of the present invention, the aforementioned test load board comprises a printed circuit board (PCB). The wafer comprises a chip and the substrate is used for chip packaging.

The present invention provides a test module for wafer, which comprises a test load board, a spring pin socket, a substrate, and a plurality of bumps. The test load board has a plurality of first contacts. The spring pin socket in which a plurality of pogo pins is arranged is disposed on the test load board. The substrate is fixed on the spring pin socket. The substrate has a plurality of second contacts, and the pogo pins are electrically connected between the first contacts and the second contacts respectively. The bumps are disposed on the substrate to electrically contact a wafer.

According to an embodiment of the present invention, the test module for wafer further comprises a plurality of solder balls respectively disposed on the second contacts for electrically contacting the pogo pins.

According to the test module for wafer in an embodiment of the present invention, the aforementioned substrate comprises a build-up circuit board or a laminated circuit boards.

According to the test module for wafer in an embodiment of the present invention, the aforementioned test load board comprises a printed circuit board (PCB). The wafer comprises a chip and the substrate is used for chip packaging.

The present provides a test module for wafer, which comprises a test load board, a spring pin socket, a substrate, and an anisotropic conductive adhesive. The test load board has a plurality of first contacts. The spring pin socket in which a plurality of pogo pins is arranged is disposed on the test load board. The substrate is fixed on the spring pin socket. The substrate has a plurality of second contacts, and the pogo pins are electrically connected between the first contacts and the second contacts respectively. The anisotropic conductive adhesive is disposed on the substrate to electrically contact a wafer.

According to an embodiment of the present invention, the test module for wafer further comprises a plurality of solder balls respectively disposed on the second contacts for electrically contacting the pogo pins.

According to the test module for wafer in an embodiment of the present invention, the aforementioned substrate comprises a build-up circuit board or a laminated circuit board.

According to an embodiment of the present invention, the aforementioned test load board comprises a printed circuit board (PCB). The wafer comprises a chip and the substrate is used for chip packaging.

Compared to the conventional art, as the test module for wafer of the present invention does not have the ATE interface assembly, and therefore the test module of the present invention can be lighter, thinner and have a low manufacturing cost.

In order to make the aforementioned and other objectives, features and advantages of the present invention comprehensible, preferred embodiments accompanied with figures are described in detail below.

### BRIEF DESCRIPTION OF THE DRAWINGS

FIG. 1 is a schematic view of an ATE.

FIG. 2 is a schematic view of the test module for wafer according to an embodiment of the present invention.

FIG. 3 is a schematic view of the test module for wafer according to another embodiment of the present invention.

FIG. 4 is a schematic view of the test module for wafer according to still another embodiment of the present invention.

### DESCRIPTION OF EMBODIMENTS

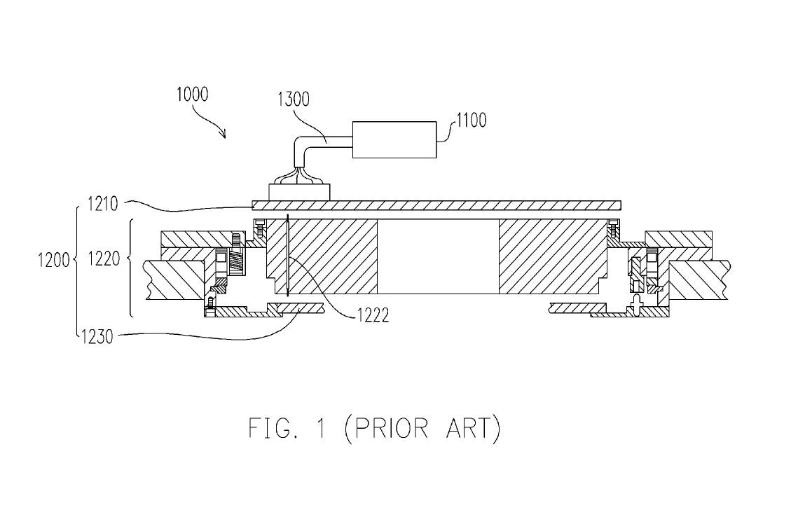

FIG. 2 is a schematic view of the test module for wafer according to an embodiment of the present invention. Referring to FIG. 2, the test module for wafer 100 mainly comprises a test load board 110, a spring pin socket 120, a substrate 130, and a plurality of probes 140. The test load board 110 has a plurality of first contacts 112 disposed on a surface 114 of the test load board 110. The test load board 110 is, for example, a PCB or a circuit board with functions as the circuit board 1210 for transmitting the test signals of the wafer test system 1100 in FIG. 1. It should be noted that the spring pin socket 120 is disposed on the test load board 110 and has a plurality of pogo pins, so as to replace the probe contact tower, the complicated docking machine and the lock mechanism of the ATE interface assembly 1220 in FIG. 1.

Moreover, the substrate 130 is fixed on the spring pin socket 120 to replace the probe card 1230 in FIG. 1, in which the probe card 1230 is expensive and difficult to assemble. The substrate 130 has a plurality of second contacts 132. One end of the pogo pins 122 is electrically connected to the first contacts 112, while the other end is electrically connected to the second contacts 132. The substrate 130 comprises, for example, a plurality of build-up circuit boards, laminated circuit boards, or circuit boards of other types. The build-up circuit board can be formed in a build-up process, subtractive process, or semi-additive process. The laminated circuit board is formed by interlaced stacking and laminating a plurality of patterned circuit layers and dielectric layers. Moreover, the probes 140 are disposed on the substrate 130 linearly or in an array, so as to electrically contact the contacts of the integrated circuit on the wafer to be tested. Furthermore, as the substrate 130 is adopted as a circuit structure with contacts to be connected with integrated circuit chip for the external signals, i.e., the substrate 130 is a chip packaging board, the substrate is already present and is unnecessary to be additionally customized or change/modify the design thereof. Compared to the probe card that is particularly customized or wired for the test, the substrate 130 can save a lot of test cost.

In the present embodiment, when the probes 140 electrically contact the contacts of the integrated circuit on the wafer, a reliable electrical contact can be achieved between the probes 140 and the contacts of the integrated circuit via the deformation of the pogo pins 122.

Moreover, when the test load board 110 of the test module for wafer 100 is electrically connected to a host of the wafer test system, and after the probes 140 of the test module for wafer 100 electrically contact the contacts of the integrated circuit on the wafer to be tested, the host of the wafer test system transmits various test signals to the integrated circuit on the wafer, and analyzes the signal fed back by the integrated circuit, so as to determine whether the circuit is qualified and to determine the electrical properties thereof.

Additionally, the test module for wafer 100 of the present embodiment can further comprise a plurality of solder balls 150. The solder balls 150 are respectively disposed on the second contacts 132, for electrically contacting the pogo pins 122.

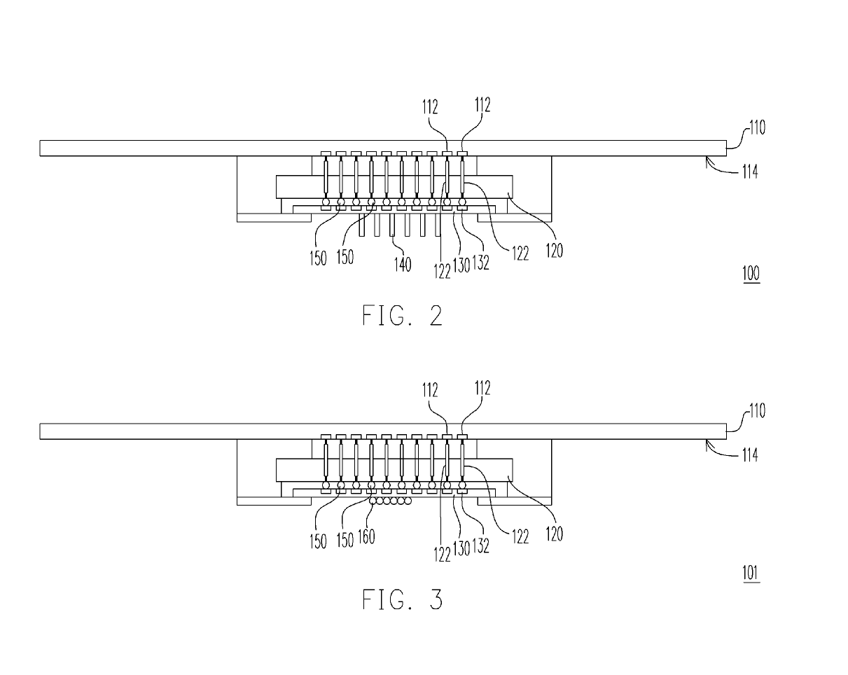

FIG. 3 is a schematic view of the test module for wafer according to another embodiment of the present invention. Referring to FIG. 3, the test module for wafer 101 mainly comprises the test load board 110, the spring pin socket 120, the substrate 130, and a plurality of bumps 160. The test load board 110 comprises plurality of first contacts 112 disposed on the surface 114 of the test load board 110. The test load board 110 is, for example, a PCB or a circuit board. The spring pin socket 120 in which the plurality of pogo pins 122 is arranged is disposed on the test load board 110.

The substrate 130 is fixed on the spring pin socket 120. The substrate 130 has a plurality of second contacts 132. One end of the pogo pins 122 is electrically connected to the first contacts 112, while the other end is electrically connected to the second contacts 132. The substrate 130 comprises, for example, a plurality of build-up circuit boards, laminated circuit boards, or circuit boards of other types. The build-up circuit board can be formed in a build-up process, subtractive process, or semi-additive process. The laminated circuit board is formed by interlaced stacking and laminating a plurality of patterned circuit layers and dielectric layers. Unlike the above embodiment, the bumps 160 are disposed on the substrate 130 linearly or in an array to replace the probes 140, so as to electrically contact the contacts of the integrated circuit on the wafer to be tested.

In the present embodiment, when the bumps 160 electrically contact the contacts of the integrated circuit on the wafer, a reliable electrical contact can be achieved between the probes 140 and the contacts of the integrated circuit via the deformation of the pogo pins 122.

Furthermore, when the test load board of the test module for wafer 101is electrically connected to a host of the ATE, and after the bumps 160 of the test module for wafer 101 electrically contact the contacts of the integrated circuit on the wafer to be tested, the host of the ATE transmits various test signals to the integrated circuit on the wafer, and analyzes the signal fed back by the integrated circuit, so as to determine whether the circuit is qualified and to determine the electrical properties thereof.

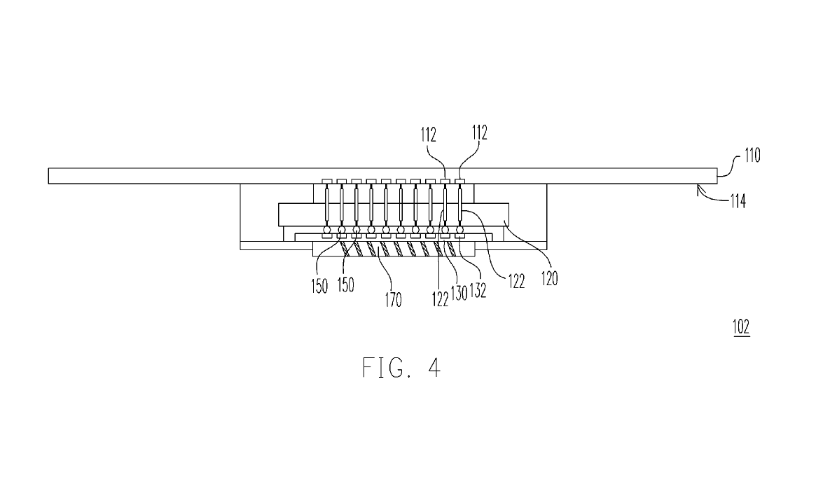

FIG. 4 is a schematic view of the test module for wafer according to still another embodiment of the present invention. Referring to FIG. 4, the test module for wafer 102 mainly comprises the test load board 110, the spring pin socket 120, the substrate 130, and an anisotropic conductive adhesive 170. The test load board 110 comprises the plurality of first contacts 112 disposed on a surface 114 of the test load board 110. The test load board 110 is, for example, a PCB or a circuit board. The spring pin socket 120 in which the plurality of pogo pins 122 is arranged is disposed on the test load board 110.

The substrate 130 is fixed on the spring pin socket. The substrate 130 has the plurality of second contacts 132. One end of the pogo pins 122 is electrically connected to the first contacts 112, while the other end is electrically connected to the second contacts 132. The substrate 130 comprises, for example, a plurality of build-up circuit boards, laminated circuit boards, or circuit boards of other types. The build-up circuit board can be formed in a build-up process, subtractive process, or semi-additive process. The laminated circuit board is formed by interlaced stacking and laminating a plurality of patterned circuit layers and dielectric layers. Unlike the above two embodiments, the anisotropic conductive adhesive 170 is disposed on the substrate 130 to replace the probes 140 or bumps 160, so as to electrically contact the contacts of the integrated circuit on the wafer to be tested.

In the present embodiment, when the anisotropic conductive adhesive 170 electrically contacts the contacts of the integrated circuit on the wafer, a reliable electrical contact can be achieved between the anisotropic conductive adhesive 170 and the contacts of the integrated circuit via the deformation of the pogo pins 122.

Furthermore, when the test load board of the test module for wafer 102 is electrically connected to a host of the ATE, and after the anisotropic conductive adhesive 170 of the test module for wafer 102 electrically contacts the contacts of the integrated circuit on the wafer to be tested, the host of the ATE transmits various test signals to the integrated circuit on the wafer, and analyzes the signal fed back by the integrated circuit, so as to determine whether or not the circuit is qualified and determine the electrical properties thereof.

Compared to the conventional art, the test module for wafer of the present invention adopts the existing test load board, spring pin socket, and substrate to replace the complicated ATE interface assembly and the substrate is a board used in chip packaging. Thus, the present invention uses fewer test components to serve as the interface for test signal transmission, and therefore the manufacturing cost can be reduced and maintenance thereof is minimized. Furthermore, according to practical requirements, the present invention can adopt probes, bumps, or an anisotropic conductive adhesive to electrically connect the contacts of the integrated circuit on the wafer, thereby achieving a reliable electrical connection between the test module for wafer and the integrated circuit.

Though the present invention has been disclosed above by the preferred embodiments, they are not intended to limit the present invention. Anybody skilled in the art can make some modifications and variations without departing from the spirit and scope of the present invention. Therefore, the protecting range of the present invention falls in the appended claims.

What is claimed is:

1. A test module for wafer, comprising:
a test load board, having a plurality of first contacts;
a spring pin socket, disposed on the test load board, comprising a plurality of pogo pins disposed therein;
a substrate, fixed on the spring pin socket, comprising a plurality of second contacts, wherein the pogo pins are electrically connected between the first contacts and the second contacts respectively; and
a plurality of probes, disposed on the substrate, for electrically contacting a wafer.

2. The test module for wafer according to claim 1, further comprising a plurality of solder balls respectively disposed on the second contacts for electrically contacting the pogo pins.

3. The test module for wafer according to claim 1, wherein the substrate comprises a build-up circuit board or a laminated circuit board.

4. The test module for wafer according to claim 1, wherein the test load board comprises a printed circuit board (PCB).

5. The test module for wafer according to claim 1, wherein the wafer comprises a chip and the substrate is used for chip packaging.

6. A test module for wafer, comprising:
a test load board, comprising a plurality of first contacts;
a spring pin socket, disposed on the test load board, comprising a plurality of pogo pins disposed therein;
a substrate, fixed on the spring pin socket, comprising a plurality of second contacts, wherein the pogo pins are electrically connected between the first contacts and the second contacts respectively; and
a plurality of bumps, disposed on the substrate, for electrically contacting a wafer.

7. The test module for wafer according to claim 6, further comprising a plurality of solder balls respectively disposed on the second contacts for electrically contacting the pogo pins.

8. The test module for wafer according to claim 6, wherein the substrate comprises a build-up circuit boards or a laminated circuit board.

9. The test module for wafer according to claim 6, wherein the test load board comprises a printed circuit board (PCB).

10. The test module for wafer according to claim 6, wherein the wafer comprises a chip and the substrate is used for chip packaging.

11. A test module for wafer, comprising:
a test load board, comprising a plurality of first contacts;
a spring pin socket, disposed on the test load board, comprising a plurality of pogo pins disposed therein;
a substrate, fixed on the spring pin socket, comprising a plurality of second contacts, wherein the pogo pins are electrically connected between the first contacts and the second contacts respectively; and
an anisotropic conductive adhesive, disposed on the substrate, for electrically contacting a wafer.

12. The test module for wafer according to claim 11, further comprising a plurality of solder balls respectively disposed on the second contacts for electrically contacting the pogo pins.

13. The test module for wafer according to claim 11, wherein the substrate comprises a build-up circuit board or a laminated circuit board.

14. The test module for wafer according to claim 11, wherein the test load board comprises a printed circuit board (PCB).

15. The test module for wafer according to claim 11, wherein the wafer comprises a chip and the substrate is used for chip packaging.
